(19) United States
(12) Patent Application Publication
(10) Pub. No.: US 2022/0238354 A1
(43) Pub. Date: Jul. 28, 2022

(54) MULTIPLE VACUUM CHAMBER EXHAUST SYSTEM AND METHOD OF EVACUATING MULTIPLE CHAMBERS

(71) Applicant: Edwards Vacuum LLC, Sanborn, NY (US)

(72) Inventors: Declan Scanlan, San Jose, CA (US); Karena Lynn Shannon, San Jose, CA (US); Dawn Stephenson, San Jose, CA (US)

(21) Appl. No.: 17/617,244

(22) PCT Filed: Jun. 12, 2020
(86) PCT No.: PCT/IB2020/055525

§ 371 Date: Dec. 7, 2021

(30) Foreign Application Priority Data
Jun. 19, 2019 (GB) 1908781.6

(51) Int. Cl. H01L 21/67; C23C 16/44; F04D 19/04

(52) U.S. Cl. CPC H01L 21/67017; F04D 19/04; C23C 16/4412

(57) ABSTRACT

A vacuum exhaust system and method of evacuating a plurality of chambers is disclosed. The vacuum exhaust system is within a clean room and comprises: a plurality of branch process gas channels each configured to connect to a corresponding chamber and a shared process channel formed from a confluence of the branch channels and configured to provide a shared fluid communication path for process gas from each of the chambers to flow from the clean room to a process channel outside of the clean room. There is also a plurality of branch pumpdown channels each configured to connect to a corresponding chamber and a shared pumpdown channel formed from a confluence of the branch pumpdown channels and configured to provide a fluid communication path for fluid to flow from the clean room to a pumpdown channel outside of the clean room during pumpdown of at least one of the vacuum chambers.

This application is a national stage entry under 35 U.S.C. § 371 of International Application No. PCT/IB2020/055525, filed Jun. 12, 2020 and entitled “MULTIPLE VACUUM CHAMBER EXHAUST SYSTEM AND METHOD OF EVACUATING MULTIPLE VACUUM CHAMBERS,” which claims the benefit of GB Application No. 1908781.6, filed Jun. 19, 2019 and entitled “MULTIPLE VACUUM CHAMBER EXHAUST SYSTEM AND METHOD OF EVACUATING MULTIPLE CHAMBERS,” the entire contents of each of which are incorporated herein by reference.

### TECHNICAL FIELD

The present disclosure relates to a vacuum exhaust manifold and a method and system for evacuating gas from multiple chambers such as process chambers used in semiconductor fabrication.

### BACKGROUND

Semiconductor fabrication plants have multiple vacuum chambers located in a clean room to reduce the chance of contamination. They require a low stable pressure to be maintained within each chamber. This is conventionally done by a vacuum exhaust system comprising a turbomolecular pump attached to the vacuum chamber with a booster and a backing pump attached to the turbomolecular pump's exhaust. The backing pump and booster pump may be located outside of the clean room in the subfab to reduce contamination and vibrations within the clean room.

The semiconductor processes within each chamber are asynchronous, cyclic and intermittent with the type and amount of gas being evacuated varying over time. The gas produced by the reaction with the process gas (the reaction product gas) and the residuum of the process gas are exhausted to the exterior of the chamber by the vacuum exhaust system, where they may be fed to an abatement system.

Thus, the exhaust system for such chambers should be able to evacuate different and varying amounts of gases and generate and maintain a stable high vacuum. The typical set-up for etch systems in production today is for a dedicated backing pump for each process chamber.

It would be desirable to share pumps across multiple semiconductor processing chambers to reduce the overheads associated with the multiple pumps while still providing a stable high vacuum within each chamber.

### SUMMARY

A first aspect provides a vacuum exhaust system for evacuating a plurality of chambers located within a clean room, said vacuum exhaust system comprising: a plurality of branch process gas channels each configured to connect to a corresponding chamber; a shared process channel formed from a confluence of said branch channels and configured to provide a shared fluid communication path for process gas from each of said chambers to flow from said clean room to a process channel outside of said clean room during processing; and a plurality of branch pumpdown channels each configured to connect to a corresponding chamber; a shared pumpdown channel formed from a confluence of said branch pumpdown channels and configured to provide a fluid communication path for fluid to flow from said clean room to a pumpdown channel outside of said clean room during pumpdown of at least one of said vacuum chambers.

In the field of semiconductor processing such as wafer etching, it is desirable for the vacuum chambers in a vacuum system to be matched so that wafers processed in each chamber are substantially identical. In order to achieve this each chamber should provide substantially the same vacuum environment at the same stage in the process. This requirement is conventionally addressed by providing each chamber with the same piping arrangement feeding similar pumps. The inventors of the present disclosure recognised that one way in which such matching could be performed “automatically” would be with the use of shared pump(s) and shared piping/channels within the tool/clean room. Such an arrangement would provide automatic matching of the vacuum piping and pumps and there would also be a considerable saving in piping and pumps. Although there are advantages associated with sharing pumps within a system, there are also potential drawbacks associated with this. In particular, the shared pipe which connects the vacuum chambers with the remote pumps provides a path between chambers, such that a pressure spike in one chamber will be conveyed to the shared pipe and may affect the pressure in the other chambers. In a semiconductor processing system, the different vacuum chambers generally perform the different processing steps at different times, and thus, the pressures within the different chambers will vary at different times. Furthermore, they will periodically by vented and need to be pumped back down to the high vacuum of operation. Thus, where one chamber experiences a pressure spike due perhaps to venting and subsequent pumpdown, this will affect the vacuum in the shared pipe and thus, the vacuum felt in the other chambers.

The inventors of the present disclosure recognised the advantages of sharing pumps and realised that the disadvantages could be mitigated by providing separate pumping channels for pumping during pumpdown and for pumping during processing. Thus, pressure spikes from the pumpdown of one chamber are isolated from the process gas shared channel and thus, do not affect the pressure in the other chambers. Providing an additional pumpdown channel is not as large an overhead in hardware or space as might be expected as the pumpdown channels can have a relatively small cross section as the gases evacuated are at a relatively high pressure. Furthermore, these channels do not need to be heated as they do not conduct process gases. Both the pumpdown and process gas channels are shared channels, with one channel exiting the clean room for the process gas and one channel for the gases evacuated during pumpdown. It should be noted that the process gases transmitted by the process channels comprise the process gases fed to the chamber and the gas products of the reactions in the chambers.

In some examples, said vacuum exhaust system further comprises a plurality of vacuum pumps for evacuating said plurality of chambers, said plurality of vacuum pumps being configured to connect to said corresponding plurality of vacuum chambers, said plurality of branch process gas channels being connected to a corresponding exhaust of said plurality of vacuum pumps.

In some examples, said vacuum pumps comprise high vacuum vacuum pumps configured to operate in the molecular flow region of the gas being evacuated.

The vacuum chambers may have a high vacuum vacuum pump such as a turbomolecular pump attached to them, where the chambers require a high vacuum such as during etching processes. Where the pump is a turbomolecular pump then it is particularly important to maintain a steady pressure in the shared process gas channel as changes in pressure at the exhaust of a turbomolecular pump affects its pumping speed and thus, the vacuum that it produces.

In some examples, said vacuum exhaust system further comprises a process lower vacuum vacuum pump configured to operate in a viscous flow region of said gas, said process lower vacuum vacuum pump being connected to said process channel located outside of said clean room; and a pumpdown vacuum pump configured to operate in a viscous flow region of said gas, said pumpdown vacuum pump being connected to said pumpdown gas channel located outside of said clean room.

The use of a shared process gas channel and a shared pumpdown gas channel allows a single process vacuum pump and a single pumpdown vacuum pump to be located outside of the clean room. These pumps may be backing pumps for the high vacuum vacuum pumps or where the chambers are used for deposition for example, they may be the pumps used to evacuate the chambers. In any case, they are often dry pumps and are located outside of the clean room in the subfab to isolate the chambers from the vibrations of such pumps. The space within the subfab is limited so that being able to provide a single vacuum pump for multiple vacuum chambers for pumping process gases and a single pump for pumpdown, significantly decreases the amount of space occupied by the pumps in the subfab and can be very advantageous.

In some examples, said plurality of branch process gas channels are configured such that the effective conductance of each branch channel is substantially the same, the effective conductance varying by less than 20%, preferably by less than 10% between each of said branch channels.

As noted previously it is advantageous if the chambers are matched and thus, the vacuum system for each chamber should be substantially the same. Where they use a shared pump, then the pump will be the same for each chamber, and in order to provide effective chamber matching it is advantageous if the piping is also the same, or rather the effective conductance of the branch channels, which are the non-shared channels are substantially the same or at least vary by less than 20%. That is the branch channel with the highest effective conductance has an effective conductance that is less than 20% greater than the branch channel with the lowest effective conductance.

In some examples, said vacuum exhaust system further comprises: a control module, said control module comprising pressure control circuitry configured to generate control signals for controlling a pressure in said shared process channel.

As noted previously it is desirable to reduce any fluctuations in the pressure in the shared process channel. Having a separate pumpdown channel and pumpdown pump helps reduce fluctuations, however, they can be further reduced by using a pressure control system that generates control signals to control a pressure in the shared process channel. Such control may be performed in order to reduce fluctuations in pressure that the control circuitry determines from received measurements or that it predicts from other received signals.

In some examples, said vacuum exhaust system further comprises: a pressure sensor for monitoring a pressure within said shared process channel; said pressure control circuitry being configured to receive signals from said pressure sensor and to generate at least one of said control signals in response to at least one of said received signals in order to reduce fluctuations in said monitored pressure.

One way in which pressure can be controlled is to have a pressure sensor associated with the shared line and in response to measurements indicating changes in pressure control signals to combat the changes may be generated.

Alternatively and/or additionally in some examples, said pressure control circuitry is configured to receive signals indicative of activity within at least one of said chambers, said pressure control circuitry being configured to generate at least one of said control signals in response to at least one of said received signals indicative of said activity.

The pressure control circuitry may receive signals indicative of activity within the chambers. They may be from sensors within the chambers or they may be from control circuitry controlling the processing within the chambers. Receiving signals indicative of activity within the chambers allows the control circuitry to generate pressure control signals that can vary the pressure in the shared channel in order to address changes in the pressure that will arise from the activity in the chambers.

In some examples, said pressure control circuitry is configured to receive signals indicative of a future activity within at least one of said chambers, said pressure control circuitry being configured to generate at least one of said control signals in response to said received signals indicative of said future activity.

The signals may not only indicate current activity they may also indicate future activity in the chamber, this may be a predicted activity from detected previous and/or current activities, or it may be an indication of a future activity from the semiconductor control circuitry. Where the signals indicate a future activity then the control signals can be proactive and signals to change the pressure in the shared channel can be generated before any changes in pressure are felt, allowing pressure fluctuations to be still further reduced.

In some examples, at least one of said control signals generated by said pressure control circuitry is a control signal for controlling a pumping speed of at least one of said high vacuum vacuum pumps or said process lower vacuum vacuum pump.

One way in which the pressure in the system and in particular, in the shared pumping channel can be controlled is by controlling the speed of one or more of the pumps within the system.

In some examples, said vacuum exhaust system further comprises: a purge gas inlet for providing a controlled flow of purge gas to said shared process channel; at least one of said control signals generated by said pressure control circuitry being a control signal for controlling said flow of purge gas.

Alternatively and/or additionally the system may comprise a controllable purge gas supply for controlling the amount of purge gas supplied to the shared process channel and thus, the pressure in the shared process gas channel.

In some examples, at least one of said process channels comprises at least one variable restrictor.

Alternatively and/or additionally in some examples pressure may be controlled using a variable restrictor in one or more of the process channels, at least one of said control signals generated by said pressure control circuitry being a control signal for controlling said at least one variable restrictor.

In some examples, said vacuum exhaust system comprises a plurality of valves, said plurality of valves comprising: a plurality of process valves for isolating or connecting said plurality of chambers to said corresponding plurality of branch process channels; and a plurality of pumpdown valves for isolating or connecting said plurality of chambers to said corresponding plurality of branch pumpdown channels.

The vacuum exhaust system may comprise valves to allow the process line or pumpdown lines to be connected to each vacuum chamber.

In some examples, at least one of said control signals generated by said control module is a control signal for controlling at least one of said plurality of valves.

The control module may also control the valves that interconnect the pumpdown channels and process gas channels to the different chambers. Having a central control module to control the pressure in the shared process channel and to control the valves during pumpdown, allows fluctuations in pressure that would arise from the different connections to be predicted and mitigated for.

In some examples, said control module further comprises pump monitoring circuitry for monitoring signals received from sensors associated with said pumps, wherein said signals received from said sensors comprise at least one of an indication of a current supplied to a motor for driving said pumps, and a signal from a vibration sensor indicative of vibrations generated by said pump.

The control module may also receive signals from sensors associated with the pumps, allowing it to monitor and control operation of the pumps. The signals received from the pumps may be indicative of their health, and may be used to determine when the pumps should be serviced. The control module can then control the valves and operation of any backup pumps to isolate the pump requiring service from the system and in some cases to replace it with a backup pump.

In some examples, said system further comprises a process vacuum pump configured to operate in a viscous flow region of said gas, said process vacuum pump being connected to said process channel outside of said clean room, said system further comprising an abatement module configured to receive a flow of gas from said process vacuum pump, said control module being configured to transmit signals to said abatement module indicative of an amount of abatement gas to supply to said abatement module.

Having a central control module which receives signals from the processing chambers and/or signals indicative of the pressure within the shared process line and the purge gas currently being supplied, allows the control module to be aware of the amount of process gas and reaction product gases currently being exhausted by the vacuum system and needing to be abated. Such information can be used by the control module to control the abatement system to supply the required amount of gas to the abatement system, allowing it to be tuned for the current operating conditions.

A second aspect provides a vacuum system comprising a plurality of chambers connected to the vacuum exhaust system of a first aspect.

A third aspect provides a method of evacuating a plurality of vacuum chambers within a clean room, said method comprising: connecting a process gas exhaust manifold to a plurality of vacuum chambers such that a plurality of process gas branch channels connect said plurality of vacuum chambers to a shared process gas channel within a clean room; connecting a pumpdown gas exhaust manifold to a plurality of vacuum chambers such that a plurality of pumpdown branch channels connect said plurality of vacuum chambers to a shared pumpdown channel; within said clean room; evacuating said plurality of vacuum chambers through said process gas channels using a vacuum pump located outside of said clean room and connected to said shared process gas channel; monitoring a pressure in said shared process channel; and generating control signals for controlling a pressure in said shared process channel to reduce fluctuations in said monitored pressure.

In some examples, said method further comprises: receiving signals indicative of activity within at least one of said vacuum chambers; and generating at least one control signal for controlling a pressure in said shared process channel in response to at least one of said received signals in order to reduce fluctuations in said monitored pressure arising due to said activity.

In some examples, said method further comprises: receiving signals indicative of a future activity within at least one of said chambers; and generating at last one control signal for controlling a pressure in said shared process channel in response to at least one of said received signals in order to reduce fluctuations in said monitored pressure predicted to arise due to said future activity.

In some examples, said control signals comprise signals for controlling a flow of purge gas into said shared process line; and said method comprises controlling said flow of purge gas in response to said control signals.

Further particular and preferred aspects are set out in the accompanying independent and dependent claims. Features of the dependent claims may be combined with features of the independent claims as appropriate, and in combinations other than those explicitly set out in the claims.

Where an apparatus feature is described as being operable to provide a function, it will be appreciated that this includes an apparatus feature which provides that function or which is adapted or configured to provide that function.

### BRIEF DESCRIPTION OF DRAWINGS

Examples of the present disclosure will now be described further, with reference to the accompanying drawings.

FIG. 1 shows a vacuum system according to an example.

FIG. 2 shows a vacuum system and abatement system according to a further example.

FIG. 3 shows a flow diagram illustrating steps in a method for evacuating multiple vacuum chambers.

### DETAILED DESCRIPTION

Before discussing the examples in any more detail, first an overview will be provided.

Examples provide shared pumping of multiple chambers while maintaining a stable vacuum environment, by pressure control management of the common foreline manifold, and apply this within an etch system. Examples also integrate the entire vacuum system, including the chamber pumps, into one common control system. This may be driven from an OEM (original equipment manufacturer) standpoint, and could have several performance advantages over an end-user driven approach.

Examples provide a design of a vacuum layout for a multi-chamber etch system that may include:
a symmetrical or near symmetrical process vacuum line design within a mutli-chamber system that connects, via a process vacuum manifold, to a single process vacuum exit point from the etch system;
a single backing pump (with contingency backup) which connects to that etch system vacuum exit so providing vacuum to the entire system;
a vacuum control module which monitors and controls the chamber TMPs, the backing pump, and the pressure management system of the process vacuum manifold.

Examples provide a vacuum exhaust system for multiple vacuum chambers used for semiconductor processing such as wafer etch or wafer deposition. Within such processing systems it is desirable that the vacuum chambers show the same conditions to each of the wafers such that uniform wafers are generated in each of the chambers. Such systems also have space constraints, particularly in the subfab underneath the clean room where the backing or dry pumps are generally located. The amount of space available for such pumps is constrained. Furthermore, multiple pumps can be expensive and can also be difficult to provide uniform pumping. Examples provide a shared pump between the chambers with a single process gas line exiting the clean room into the subfab.

Examples provide a single pumpdown pump provided with a single pumpdown line exiting the clean room such that when the chambers are pumped down from atmosphere during servicing for example a different pump to the process gas pump is used and the spikes in pressure that use of the process gas pipe and pump during pumpdown can generate are avoided or at least reduced. In some cases, although there is only a single process gas pump operating at any one time there may be two process gas pumps within the subfab one being a backup pump to provide pumping operation when the other pump is being serviced for example.

Although, the only vacuum pumps used in the system may be those in the subfab, this being the case where the processing stage is deposition or some other processing step that does not require a high vacuum, in some examples, there are high vacuum pumps such as turbo pumps attached to each of the chambers and the exhausts of these pumps are connected to the process gas line via branch process gas pipes which then each connect to the shared process gas line which exits the clean room and takes the process gas to a pump in the subfab. In examples the process gas lines or channels are designed to be symmetrical so that each chamber sees the same effective conductance or at least very similar effective conductance. In this regard, the design is such that the effective conductance provided by the pipes from each chamber is within 20% preferably within 10% of each other. That is the maximum conductance seen by any chamber is at the most 20% higher than the minimum conductance seen by any other chamber and preferably within 10% of the value.

Examples also provide a central control module which is configured for pressure control within the shared process gas line allowing pressure variations in this line to be reduced and thus, providing more uniform conditions within each of the chambers. In this regard, examples provide pressure control circuitry which may include a pressure sensor and a controllable purge gas supply for supplying purge gas to the shared process gas line. The supply of purge gas is increased to compensate for falls in gas flow from the chambers and decreased to compensate for increases in gas flows from the chambers. In this regard, the pressure control system may act reactively to these changes by sensing the pressure changes within the shared pipe and altering the purge gas flow in response to these detected changes. Alternatively and/or additionally the control circuitry may be proactive and predict changes in the pressure within the shared pipe and adjust the purge gas flow before such changes are detected. In this regard, the central control module may receive signals from the system controlling the chambers and in such a case, the signals may indicate when changes in processing in the chambers are to occur or the circuitry may predict from the signals indicating current activity which activity is to occur next and in response to this appropriate control signals may be generated to compensate for any changes in gas flow output form the chambers. In this way by having a central control system a reduction in pressure fluctuations in a shared process gas channel can be achieved.

In some cases, the central control system may also be used to monitor the health of the pumps by monitoring for example the current supplied to them and/or the vibrations generated by the pumps. From these signals the control circuitry may determine when such pumps may need servicing. The central control module may also be able to use to control an abatement system downstream of the pumps within the subfab. In this regard the quantity of abatement gases required depends on the amount of process and reaction product gases that are being output from the multiple chambers. Where the control module has access to signals from the chamber control system, it will have at least some visibility of the processing steps being performed and will be able to provide signals to the abatement system controlling the amount of abatement gases that are currently required in dependence upon the amount of process gases output. This can have a significant effect on reducing the amount of abatement gases used in the abatement process.

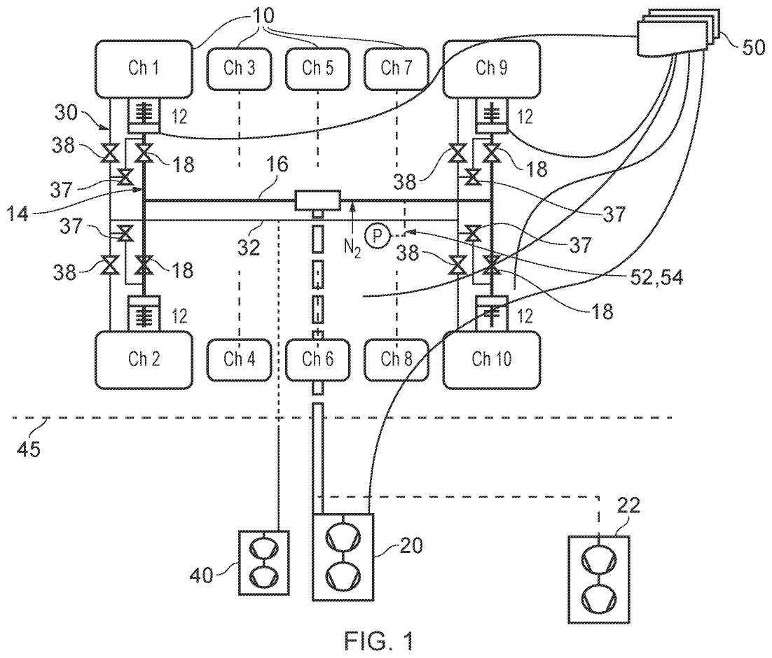

FIG. 1 shows a vacuum system according to a first embodiment. In this embodiment, the vacuum system has ten chambers 10 each having their own turbomolecular pump 12 connected to the chambers. There are chamber valves in the form of poppet valves not shown, which can isolate or connect the turbomolecular pumps 12 from the chambers. There are branch pipes or channels 14 leading from each of the turbomolecular pumps' exhausts to a shared pipe 16 which shared pipe takes process gas from all of the chambers and exits the clean room via an outlet in the clean room floor 45 thereby conducting the process gases to a backing pump 20 in the subfab. In this embodiment there is also a backup backing pump 22.

In addition to the process gas branch lines 14 and shared lines 16 there are also pumpdown channels from each of the chambers for use during pump down of the chambers when they have been vented. These are shown as branch pumpdown lines 30 and a shared pumpdown line 32. As for the process gas lines these exit the clean room via a single point and connect to a pumpdown dry pump 40 within the subfab. As the pumpdown pump 40 is used to pump down chambers that have been vented to atmosphere, these pipes 30, 32 can be significantly smaller than the process gas pipes 14, 16 which operate at higher vacuums. Furthermore, they do not transmit process gases and as such do not require the heating that the process gas channels may require to avoid deposition of substances. Thus, although the providing of a separate exhaust system for pumpdown has some overhead, the overhead is not as large as were a separate process gas exhaust system provided and it does have the advantage of isolating many of the pressure spikes occurring during pumpdown from the shared process channel 16.

In order to control the evacuation of the different chambers there are valves provided both on the pumpdown lines 30, 32 and on the process gas lines 14, 16. Downstream of the exhaust of each turbomolecular pump there is a valve 18 which is able to isolate both the turbomolecular pump 12 and the chamber from the process gas vacuum line 14. This can be used when the chamber and the turbomolecular pump needs servicing. There are also valves 38 on the pumpdown lines within each branch channel 30 of the pumpdown line isolating the chamber from the pumpdown line when the pump chamber is not being pumped down. In some examples there is also a line between the pumpdown branch channel 30 and the process gas branch channel 14 and this connecting channel will have its own valve 37. This valve allows the chamber and turbomolecular pump to be pumped down together, where the turbomolecular pump has been vented as it needs servicing. In this regard, there is also a chamber valve between the chamber and the turbomolecular pump which is used when the chamber is to be vented. Venting of the chamber is a more common occurrence than venting of the turbomolecular pump.

In this example there is a vacuum control module 50 which is used to provide central control of the vacuum system. Vacuum control module 50 provides pressure control for maintaining uniform pressure within the shared process gas line 16 and reducing any pressure fluctuations.

In order to provide pressure control the control module 50 may control a purge gas supply 54 which provides a controllable flow of purge gas into the shared channel 16. The control module 50 may also be configured to control the different pumps within the system and the valves. In some cases there may be controllable restrictions within at least some of the pipes to control the conductance of the pipes and these may also be controlled by the central control module 50.

In some examples, the control module 50 receives signals from the chambers such that it has visibility of activity within the chambers. These signals may come from sensors associated with the chambers or from control circuitry for controlling the processing within the chambers. In some examples the central control module 50 may include the control circuitry for controlling the processes within the chambers as well as the control circuitry for controlling the vacuum exhaust system. The central control module 50 may also be configured to control the dry pumps 20, 40 within the subfab.

In some examples, the vacuum control module 50 provides pressure control within the shared channel 16 by monitoring the pressure within the shared channel using pressure sensor 52. In response to detected variations in the monitored pressure, control module 50 sends control signals to purge gas supply 54 to vary the amount of purge gas supplied to the shared channel in order to compensate for any pressure changes detected. Alternatively and/or additionally the vacuum control module 50 may have a more proactive predictive role and may determine from signals received from the chambers the different processes being performed and from these predict changes in gas flow and control the purge gas supply 54 in advance of or synchronously with these predicted changes. The control module 50 may also control the valves and the pumps themselves in response to these received signals such that pumping speeds may be varied depending on the process step being performed and valves may be opened or closed as the chambers require servicing or venting.

In some examples the vacuum control module 50 may also receive signals from sensors associated with the pumps which signals provide indications of the health of the pumps such as the current used to the drive the turbomolecular pumps 12 or vibrations generated by the pumps in the sub fab. Where for example, there are significant changes in the current required to drive a turbomolecular pump this is indicative of the pump requiring servicing. Similarly, vibration sensors associated with the dry pumps 40, 20 may indicate that they also require servicing. Where this is the dry pump 20 which has a backup pump 22 then the pump 20 may be disconnected from the system using a valve not shown and the backup pump used as the pump for the system.

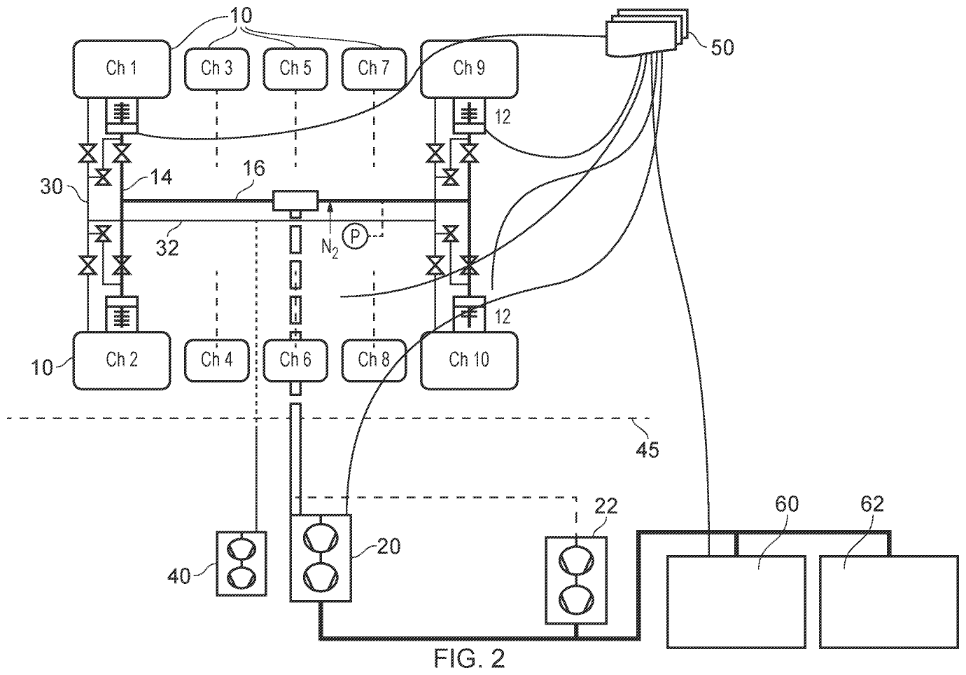

FIG. 2 shows an alternative embodiment, similar to the embodiment of FIG. 1 but which additionally has an abatement system 60, 62 attached to the process pumps for abating the process and reaction product gases output from the vacuum system. This abatement system 60 can also be controlled by the vacuum control module 50 and the quantity of abatement gases sent to the abatement system can be varied depending on the amount and type of gases currently being output from the vacuum system. This can be determined by the central control module where it receives signals from the chambers indicative of their current and/or future activities. In this way, a more efficient and environmentally friendly system for abatement is provided. The abatement system 60, may have a backup abatement system 62 for use while system 60 is being serviced for example.

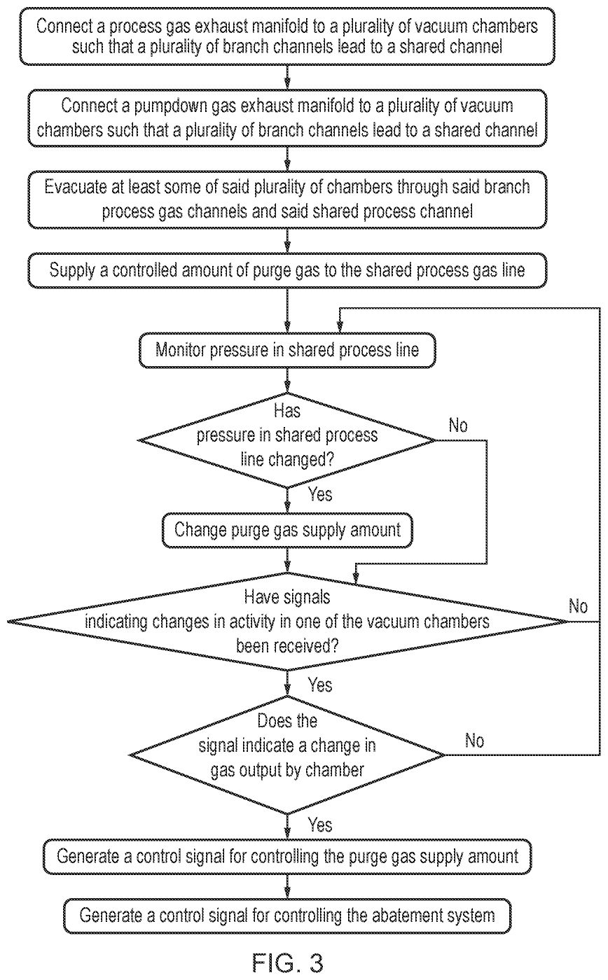

FIG. 3 shows a flow diagram illustrating steps S10 to S110 in a method for evacuating multiple vacuum chambers according to an embodiment. A process gas exhaust manifold comprising a plurality of branch channels leading to a shared channel is connected to a corresponding plurality of vacuum chambers in step S10. A pumpdown exhaust manifold comprising a plurality of branch channels leading to a shared channel is also connected to the corresponding plurality of vacuum chambers in step S20. At least some of the chambers are then evacuated through the process gas channels in step S30, the pumped gas exiting the clean room via the shared process gas channel and passing through a shared pump operating in the viscous flow region located in the subfab. In some examples each chamber has a turbomolecular pump between the process branch channel and the vacuum chamber.

A controlled amount of purge gas is supplied to the shared process gas line in step S40 to maintain a substantially constant pressure within this line. The pressure in the shared process line is monitored in step S50 using a pressure sensor and where changes are detected at step S60 the amount of purge gas supplied is changed at step S70 in order to counteract the detected changes. Where no changes are detected or following step S70, step S80 is performed where it is determined if signals have been received indicative of changes in activity within one or more of the chambers. These changes in activity may mean that the amount and/or type of gas exhausted from the chambers changes, and thus where this is determined to be the case in step S90, a control signal is generated to change the purge gas amount at step S100 in order to counteract any of the changes in gas flow from the chambers and render the pressure within the shared process gas line substantially stable.

Additionally such signals may be used to control the abatement system in step S110, such that where an amount and perhaps type of gas exhausted by the chambers is signalled to change in step S90 the amount of abatement gas needed will also change and thus, these signals can be used to control the abatement system in step S110 and in particular the amount of gas used in the abatement system and thereby render it more efficient.

In summary, examples provide vacuum chambers where the chambers are matched and the wafers within the different chambers see substantially the same vacuum environment. Examples are fully integrated with symmetrical piping, that is piping that has the same effective conductance. By providing a shared process line and a shared pump matching occurs automatically to some extent and by providing a pressure control system and a separate backup line the pressure fluctuations that different processes within different chambers may produce are mitigated.

Using a central control system to control the vacuum system, the processing system and also the abatement system allows the abatement system to be tuned to the current conditions and means that it does not have to be turned up to maximum all of the time, which tuning leads to a more efficient system.

The central control module may receive signals from the chambers and this allows changes in the gas flow to be predicted rather than simply detected such that they can be responded to prior to the pressure changes occurring in the shared line. This in turn allows for more effective pressure control and a reduction in pressure fluctuations.

In some examples there is also a communications and control link between the abatement system and the vacuum control module, enabling integration of the exhaust gas management control system into the general processing control system.

Although illustrative examples of the disclosure have been disclosed in detail herein, with reference to the accompanying drawings, it is understood that the disclosure is not limited to the precise embodiment and that various changes and modifications can be effected therein by one skilled in the art without departing from the scope of the disclosure as defined by the appended claims and their equivalents.

1. A vacuum exhaust system for evacuating a plurality of chambers located within a clean room, the vacuum exhaust system comprising:
a plurality of branch process gas channels each configured to connect to a corresponding chamber;
a shared process gas channel formed from a confluence of the plurality of branch process gas channels and configured to provide a shared fluid communication path for process gas from each of the plurality of chambers to flow from the clean room to a process channel outside of the clean room;
a plurality of branch pumpdown channels each configured to connect to a corresponding chamber; and
a shared pumpdown channel formed from a confluence of the plurality of branch pumpdown channels and configured to provide a fluid communication path for fluid to flow from the clean room to a pumpdown channel outside of the clean room during pumpdown of at least one of the plurality of chambers.

2. The vacuum exhaust system according to claim 1, the vacuum exhaust system further comprising a plurality of vacuum pumps configured to evacuate the plurality of chambers, the plurality of vacuum pumps configured to connect to the corresponding plurality of chambers, the plurality of branch process gas channels connected to a corresponding exhaust of the plurality of vacuum pumps.

3. The vacuum exhaust system according to claim 2, wherein the plurality of vacuum pumps comprise a plurality of high vacuum vacuum pumps configured to operate in the molecular flow region of the process gas being evacuated.

4. The vacuum exhaust system according to claim 1, the vacuum exhaust system further comprising:
a lower vacuum vacuum pump configured to operate in a viscous flow region of the process gas, the lower vacuum vacuum pump connected to the process channel located outside of the clean room; and
a pumpdown vacuum pump configured to operate in a viscous flow region of the process gas, the pumpdown vacuum pump being connected to the pumpdown gas channel located outside of the clean room.

5. The vacuum exhaust system according to claim 1, wherein the plurality of branch process gas channels are configured such that the effective conductance of each of the plurality of branch process gas channels is substantially the same, the effective conductance varying by less than 20%, preferably less than 10% between each of the plurality of branch process gas channels.

6. The vacuum exhaust system according to claim 1, the vacuum exhaust system further comprising:
a control module, the control module comprising pressure control circuitry configured to generate control signals that control for controlling a pressure in the shared process gas channel.

7. The vacuum exhaust system according to claim 6, the vacuum exhaust system further comprising:
a pressure sensor configured to monitor for monitoring a pressure within the shared process gas channel;
the pressure control circuitry being configured to receive signals from the pressure sensor and generate at least one of the control signals in response to at least one of the received signals in order to reduce fluctuations in the monitored pressure.

8. The vacuum exhaust system according to claim 6, the pressure control circuitry being configured to receive signals indicative of activity within at least one of the plurality of chambers, the pressure control circuitry being configured to generate at least one of the control signals in response to at least one of the received signals indicative of the activity.

9. The vacuum exhaust system according to claim 6, the pressure control circuitry being configured to receive signals indicative of a future activity within at least one of the plurality of chambers, the pressure control circuitry being configured to generate at least one of the control signals in response to the received signals indicative of the future activity.

10. The vacuum exhaust system according to claim 6, the vacuum exhaust system further comprising at least one of:
a plurality of vacuum pumps configured to evacuate the plurality of chambers, the plurality of vacuum pumps being configured to connect to the corresponding plurality of chambers, the plurality of branch process gas channels connected to a corresponding exhaust of the plurality of vacuum pumps; and
a process lower vacuum vacuum pump configured to operate in a viscous flow region of the process gas, the process lower vacuum vacuum pump connected to the process channel located outside of the clean room;
wherein at least one of the control signals generated by the pressure control circuitry is a control signal that controls a pumping speed of at least one of the plurality of vacuum pumps.

11. The vacuum exhaust system according to claim 6, the vacuum exhaust system further comprising:
a purge gas inlet configured to provide a controlled flow of purge gas to the shared process gas channel;
at least one of the control signals generated by the pressure control circuitry is a control signal that controls the flow of the purge gas.

12. The vacuum exhaust system according to claim 6, the vacuum exhaust system comprising a plurality of valves, the plurality of valves comprising:
a plurality of process valves configured to isolate or connect the plurality of chambers to the corresponding plurality of branch process gas channels; and
a plurality of pumpdown valves configured to isolate or connect the plurality of chambers to the corresponding plurality of branch pumpdown channels.

13. The vacuum exhaust system according to claim 12, wherein at least one of the control signals generated by the pressure control circuitry is a control signal that controls at least one of the plurality of valves.

14. The vacuum exhaust system according to claim 6, wherein the control module further comprises pump monitoring circuitry configured to signals received from sensors associated with the plurality of pumps, wherein the signals received from the sensors comprise at least one of an indication of a current supplied to a motor for driving the plurality of said, and a signal from a vibration sensor indicative of vibrations generated by the plurality of pumps.

15. The vacuum exhaust system according to claim 6, wherein the vacuum exhaust system further comprises a process vacuum pump configured to operate in a viscous flow region of the process gas, the process vacuum pump connected to the process channel located outside of the clean room and an abatement module configured to receive a flow of gas from the process vacuum pump, the control module configured to transmit signals to the abatement module indicative of an amount of abatement gas to supply to the abatement module.

16. A vacuum system comprising:
a vacuum exhaust system for evacuating a plurality of chambers located within a clean room, the vacuum exhaust system comprising:
a plurality of branch process gas channels each configured to connect to a corresponding chamber of the plurality of chambers;
a shared process gas channel formed from a confluence of the plurality of branch process gas channels and configured to provide a shared fluid communication path for process gas from each of the plurality of chambers to flow from the clean room to a process channel outside of the clean room;
a plurality of branch pumpdown channels each configured to connect to a corresponding chamber of the plurality of chambers; and
a shared pumpdown channel formed from a confluence of the plurality of branch pumpdown channels and configured to provide a fluid communication path for fluid to flow from the clean room to a pumpdown channel outside of the clean room during pumpdown of at least one of the plurality of chambers; and
the plurality of chambers connected to the vacuum exhaust system.

17. A method of evacuating a plurality of vacuum chambers within a clean room, the said method comprising:
connecting a process gas exhaust manifold to the plurality of vacuum chambers such that a plurality of branch process gas channels connect the plurality of vacuum chambers to a shared process gas channel within a clean room;
connecting a pumpdown gas exhaust manifold to the plurality of vacuum chambers such that a plurality of branch pumpdown channels connect the plurality of vacuum chambers to a shared pumpdown channel within the clean room;
evacuating the plurality of vacuum chambers through the branch process gas channels using a vacuum pump located outside of the clean room and connected to the shared process gas channel;
monitoring a pressure in the shared process gas channel; and
generating control signals for controlling a pressure in the shared process gas channel to reduce fluctuations in the monitored pressure.

18. The method according to claim 17, the method further comprising:
receiving signals indicative of activity within at least one of the vacuum chambers; and
generating at least one control signal configured to control a pressure in the shared process gas channel in response to at least one of the received signals in order to reduce fluctuations in the monitored pressure arising due to the activity.

19. The method according to claim 17, the method further comprising:
receiving signals indicative of a future activity within at least one of the plurality of vacuum chambers; and
generating at least one control signal configured to control a pressure in the shared process gas channel in response to at least one of the received signals in order to reduce fluctuations in the monitored pressure predicted to arise due to the future activity.

20. The method according to claim 17, wherein the control signals comprise signals configured to control a flow of purge gas into the shared process gas channel; and the method comprises controlling the flow of the purge gas in response to the control signals.
